(19) United States
(12) Patent Application Publication
(10) Pub. No.: US 2024/0383742 A1
(43) Pub. Date: Nov. 21, 2024

(54) MEMS DEVICE

(71) Applicant: Zhunmao (Hangzhou) Technology Co., Hangzhou (CN)

(72) Inventor: Haitao Ding, Hangzhou (CN)

(21) Appl. No.: 18/662,378

(22) Filed: May 13, 2024

(30) Foreign Application Priority Data
May 12, 2023 (CN) 202310544887.X
Jan. 15, 2024 (CN) 202410057662.6

(51) Int. Cl. B81B 3/00; G01P 15/125

(52) U.S. Cl. CPC B81B 3/0086; G01P 15/125; B81B 2201/0221; B81B 2201/0235; B81B 2201/0242; B81B 2203/0172; B81B 2203/0307; B81B 2203/04

(57) ABSTRACT

Disclosed is a MEMS device, comprising: a sensing element, including a movable electrode plate, a first electrode plate and a second electrode plate, the first electrode plate and the movable electrode plate forming a first capacitor; the second electrode plate and the movable electrode plate forming a second capacitor; the first capacitor and the second capacitor forming a detection capacitor of the sensing element; a differential mode detection module, performing differential mode detection on the first capacitor and the second capacitor; a common mode detection module, performing common mode detection on the first capacitor and the second capacitor; and a non-linearity elimination module, performing elimination of the non-linear relationship between the capacitance variation of the detection capacitor and the displacement of the movable electrode plate using the differential mode detection module output and the common mode detection module output.

### CROSS-REFERENCE TO RELATED APPLICATION

This application claims priority to a Chinese patent application No. 202310544887.X, which is filed on May 12, 2023, and entitled “MEMS DEVICE”, and a Chinese patent application No. 202410057662.6, which is filed on Jan. 15, 2024, and entitled “MEMS DEVICE”, the entire contents of which are incorporated by reference in its entirety.

### FIELD OF THE DISCLOSURE

The present disclosure relates to a field of semiconductor technology, and in particular to a MEMS device.

### DESCRIPTION OF THE RELATED ART

Parallel-plate capacitors are easy to be fabricated, and have the advantages of high sensitivity, wide temperature range, ability to respond to a DC signal and changing little after impact, thus they are widely used in designs of Micro-Electro-Mechanical System (MEMS) sensors. In order to perform common mode signal rejection and ensure the symmetry of scale factor, differential parallel plate capacitors are usually provided with stronger practicality. However, the capacitance value of a parallel plate capacitor changes non-linearly with a distance between parallel plates, thus signal detection is also non-linear, and with an increase of the distance between the parallel plates of the parallel plate capacitor, non-linearity also increases, which seriously affects signal detection accuracy.

### SUMMARY OF THE DISCLOSURE

In view of the above problems, an objective of the present disclosure is to provide a MEMS device to eliminate non-linearity of detection based on a parallel plate capacitor.

According to a first aspect of the present disclosure, a MEMS device is provided and comprises: a sensing element, comprising a movable electrode plate, a first electrode plate located at a first side of the movable electrode plate and a second electrode plate located at a second side of the movable electrode plate, wherein the first electrode plate and the movable electrode plate form a first capacitor, the second electrode plate and the movable electrode plate form a second capacitor; the first capacitor and the second capacitor together form a detection capacitor of the sensing element; a differential mode detection module, wherein the first capacitor and the second capacitor are respectively connected to corresponding input terminals of the differential mode detection module, and the differential mode detection module is configured to perform differential mode detection on the first capacitor and the second capacitor; a common mode detection module, wherein the first capacitor and the second capacitor are respectively connected to corresponding input terminals of the common mode detection module, and the common mode detection module is configured to perform common mode detection on the first capacitor and the second capacitor; and a non-linearity elimination module, wherein an output terminal of the differential mode detection module and an output terminal of the common mode detection module are respectively connected to corresponding input terminals of the non-linearity elimination module, and the non-linearity elimination module is configured to eliminate a non-linear relationship between a capacitance variation of the detection capacitor of the sensing element and a displacement of the movable electrode plate.

Optionally, an overlapped area of the first electrode plate with the movable electrode plate is equal to an overlapped area of the second electrode plate with the movable electrode plate.

Optionally, when the movable electrode plate is in a nominal position, a distance between the first electrode plate and the movable electrode plate and a distance between the second electrode plate and the movable electrode plate are equal.

Optionally, the MEMS device includes: a first operational amplifier, wherein the first electrode plate is connected to an inverting input terminal of the first operational amplifier; and a first feedback capacitor, connected between the inverting input terminal of the first operational amplifier and an output terminal of the first operational amplifier; a second operational amplifier, wherein the second electrode plate is connected to an inverting input terminal of the second operational amplifier; and a second feedback capacitor, connected between the inverting input terminal of the second operational amplifier and an output terminal of the second operational amplifier, wherein a capacitance value of the first feedback capacitor is equal to a capacitance value of the second feedback capacitor; a subtraction module, wherein the output terminal of the first operational amplifier and the output terminal of the second operational amplifier are connected to input terminals of the subtraction module, respectively; an addition module, wherein the output terminal of the first operational amplifier and the output terminal of the second operational amplifier are connected to input terminals of the addition module, respectively; wherein the differential mode detection module is formed by the first operational amplifier, the first feedback capacitor, the second operational amplifier, the second feedback capacitor, and the subtraction module; and the common mode detection module is formed by the first operational amplifier, the first feedback capacitor, the second operational amplifier, the second feedback capacitor, and the addition module.

Optionally, the MEMS device further includes: a first demodulation and filtering module, through which the output terminal of the first operational amplifier is connected to a corresponding input terminal of the addition module and a corresponding input terminal of the subtraction module, respectively; a second demodulation and filtering module, through which the output terminal of the second operational amplifier is connected to a corresponding input terminal of the addition module and a corresponding input terminal of the subtraction module, respectively.

Optionally, the differential mode detection module includes: a first operational amplifier, wherein the first electrode plate is connected to an inverting input terminal of the first operational amplifier, and the second electrode plate is connected to a non-inverting input terminal of the first operational amplifier; a first feedback capacitor, connected between the inverting input terminal of the first operational amplifier and an output terminal of the first operational amplifier; a second feedback capacitor, connected between the non-inverting input terminal of the first operational amplifier and the output terminal of the first operational amplifier, wherein the capacitance value of the first feedback capacitor is equal to the capacitance value of the second feedback capacitor; wherein the common mode detection module comprises: a second operational amplifier, wherein the first electrode plate and the second electrode plate are connected to an inverting input terminal of the second operational amplifier, respectively; a third feedback capacitor, connected between the inverting input terminal of the second operational amplifier and an output terminal of the second operational amplifier.

Optionally, the non-linearity elimination module is a division module.

Optionally, the MEMS device further includes: a first demodulation and filtering module, through which the output terminal of the first operational amplifier is connected to a corresponding input terminal of the non-linearity elimination module; a second demodulation and filtering module, through which the output terminal of the second operational amplifier is connected to a corresponding input terminal of the non-linearity elimination module.

Optionally, the MEMS device further includes: an excitation signal, which is connected to the movable electrode plate for providing an excitation voltage (used to detect capacitance variation) to the first capacitor and the second capacitor.

Optionally, the MEMS device is a MEMS accelerometer.

Optionally, the MEMS device is a MEMS gyroscope.

According to the MEMS device provided by the present disclosure, by using common-mode detection as a reference and cooperating with a non-linearity elimination module, the non-linearity of detection on a differential parallel plate capacitor can be eliminated, thus realizing a simple method and strong feasibility.

In a preferred embodiment, the non-linearity of the detection on the differential parallel plate capacitor is eliminated by connecting the output terminal of the differential mode detection module and the output terminal of the common mode detection module to corresponding input terminals of the non-linearity elimination module, respectively, and no additional reference capacitor is required to be arranged on the sensing element.

Further, the non-linearity elimination module of the MEMS device according to some embodiments of the present disclosure can simultaneously realize the demodulation of the excitation signal, which can better restrain the temperature drift of output.

Further, the MEMS device according to embodiments of the present disclosure can be a MEMS accelerometer, a MEMS gyroscope, etc., and has a wide range of applications.

### BRIEF DESCRIPTION OF THE DRAWINGS

The foregoing and other objects, features and advantages of the present disclosure will become clearer by the following description of embodiments of the present disclosure with reference to the accompanying drawings. Obviously, the drawings in the following description relate only to some embodiments of the present disclosure and are not restrictive of the present disclosure.

FIG. 1 shows a schematic diagram of a MEMS device;

FIG. 2 shows an equivalent circuit diagram of a MEMS device;

FIG. 3 shows a schematic diagram of a MEMS device according to a first embodiment of the present disclosure;

FIG. 4 shows a schematic diagram of a sensing element of the MEMS device according to the first embodiment of the present disclosure;

FIG. 5 shows a schematic diagram of an equivalent circuit of the MEMS device according to the first embodiment of the present disclosure;

FIG. 6 shows a schematic diagram of a MEMS device according to a second embodiment of the present disclosure;

FIG. 7 shows a schematic diagram of a MEMS device according to a third embodiment of the present disclosure;

FIG. 8 shows a schematic diagram of a sensing element of the MEMS device according to the third embodiment of the present disclosure;

FIG. 9 shows a schematic diagram of a MEMS device according to a fourth embodiment of the present disclosure;

FIG. 10 shows a structural schematic diagram of a sensing element of a MEMS gyroscope.

### DETAILED DESCRIPTION OF EMBODIMENTS OF THE DISCLOSURE

The present disclosure will be described in more detail below with reference to accompanying drawings. In various figures, the same elements are denoted by similar reference numerals. For the sake of clarity, various parts in the accompanying drawings are not drawn to scale. In addition, certain well-known parts may not be shown.

The present invention may be presented in various forms, some examples of which will be described below.

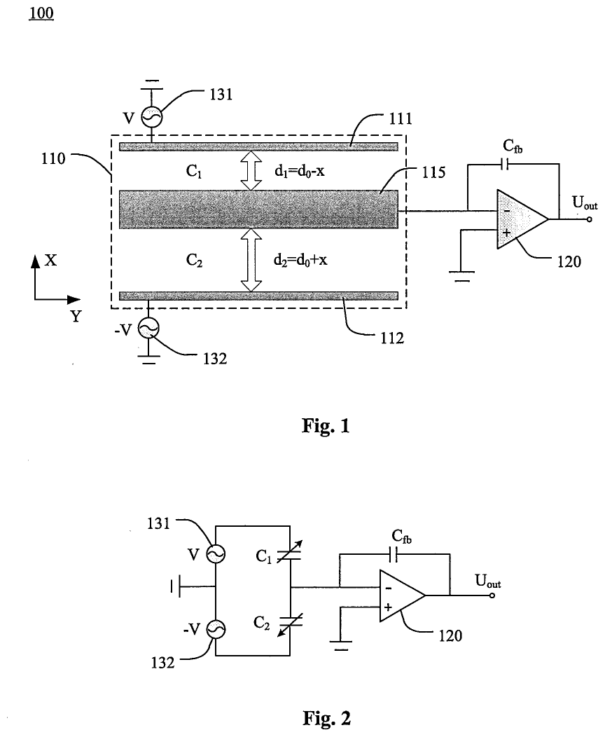

FIG. 1 shows a schematic diagram of a MEMS device; FIG. 2 shows an equivalent circuit diagram of the MEMS device in FIG. 1.

As shown in FIG. 1, the MEMS device 100 includes a sensing element 110, an operational amplifier 120, a first excitation signal 131, a second excitation signal 132, and a feedback capacitor Cp. The sensing element 110 includes a movable electrode plate 115, a first electrode plate 111 at one side of the movable electrode plate 115, and a second electrode plate 112 at the other side of the movable electrode plate 115.

The first electrode plate 111 and the movable electrode plate 115 form a first capacitor C₁, and the second electrode plate 112 and the movable electrode plate 115 form a second capacitor C₂. When the movable electrode plate is in a nominal position, the distance between the first electrode plate and the movable electrode plate and the distance between the second electrode plate and the movable electrode plate are both equal to d₀; the overlapped area of the first electrode plate 111 with the movable electrode plate 115 and the overlapped area of the second electrode plate 112 with the movable electrode plate 115 are both equal to A₀; that is, the capacitance value of the first capacitor C₁ and the capacitance value of the second capacitor C₂ are both equal to C₀. The first excitation signal 131 and the second excitation signal 132 provide high-frequency alternating voltages with equal amplitudes and opposite phases, and in a specific embodiment, the first excitation signal 131 is, for example, configured to provide a first voltage V (e.g., V=V₀ sin ωt, where V₀ represents amplitude, and ω represents frequency), the second excitation signal 132 is, for example, configured to provide a second voltage—V (e.g., V=V₀ sin ωt, where V₀ represents amplitude, and ω represents frequency).

When the movable electrode plate 115 displaces from the nominal position in a first direction (e.g., X-axis direction), the distance between the movable electrode plate 115 and the first electrode plate 111 as well as the distance between the movable electrode plate 115 and the second electrode plate 112 change, thus changing the capacitance values of the first capacitor C₁ and the second capacitor C₂.

Further, the movable electrode plate 115 is connected to an inverting input terminal of the operational amplifier 120, and the first electrode plate 111 is connected to the first excitation signal 131, so that two ends of the first capacitor C₁ are connected between the first excitation signal 131 and the inverting input terminal of the operational amplifier 120; the second electrode plate 112 is connected to the second excitation signal 132, so that two ends of the second capacitor C₂ are connected between the second excitation signal 132 and the inverting input terminal of the operational amplifier 120; the feedback capacitor C_{fb} is connected between the inverting input terminal of the operational amplifier 120 and an output terminal of the operational amplifier 120, and the first capacitor C₁ and the second capacitor C₂ are connected to form an equivalent circuit shown in FIG. 2.

As shown in FIG. 2, an output voltage Uₒᵤₜ at the output terminal of the operational amplifier is:

$${U}_{out} = - \frac{{C}_{1} - {C}_{2}}{{C}_{fb}} {V}_{0} sin ω t$$

Wherein when the movable electrode plate 115 is in the nominal position, the capacitance value of the first capacitor C₁ is equal to the capacitance value of the second capacitor C₂, and the output voltage Uₒᵤₜ is 0.

When the movable electrode plate 115 displaces in the first direction (e.g., in the X-axis direction), capacitance values of the first capacitor C₁ and the second capacitor C₂ change. For example, when the movable electrode plate 115 displaces a distance x, for example, along a direction towards the first electrode plate 111, the distance between the movable electrode plate 115 and the first electrode plate 111 is d₀−x, and the capacitance value of the first capacitor C₁ is:

$${C}_{1} = \frac{ε {A}_{0}}{{d}_{0} - x}$$

Where ε is the dielectric constant between the first electrode plate 111 and the movable electrode plate 115. At the same time, the distance between the movable electrode plate 115 and the second electrode plate 112 is d₀+x, and the capacitance value of the second capacitor C₂ is:

$${C}_{2} = \frac{ε {A}_{0}}{{d}_{0} + x}$$

Where ε is the dielectric constant between the second electrode plate 112 and the movable electrode plate 115.

The output voltage Uₒᵤₜ at the output terminal of the operational amplifier 120 is as follows:

$${U}_{out} = - \frac{{C}_{1} - {C}_{2}}{{C}_{fb}} {V}_{0} sin ω t = - \frac{\frac{ε {A}_{o}}{{d}_{o} - x} - \frac{ε {A}_{o}}{{d}_{o} + x}}{{C}_{fb}} {V}_{0} sin ω t = - \frac{2 ε {A}_{0} {V}_{0} sin ω t}{{C}_{fb}} \frac{x}{( {d}_{0} + x ) ( {d}_{0} - x )}$$

The feedback capacitor C_{fb} is a fixed capacitor. From the above formula, it can be known that the capacitance value of the sensing element 110 changes with distance non-linearly, the output voltage also changes with distance non-linearly, and with an increase of distance variation, non-linearity also increases, which seriously affects detection accuracy.

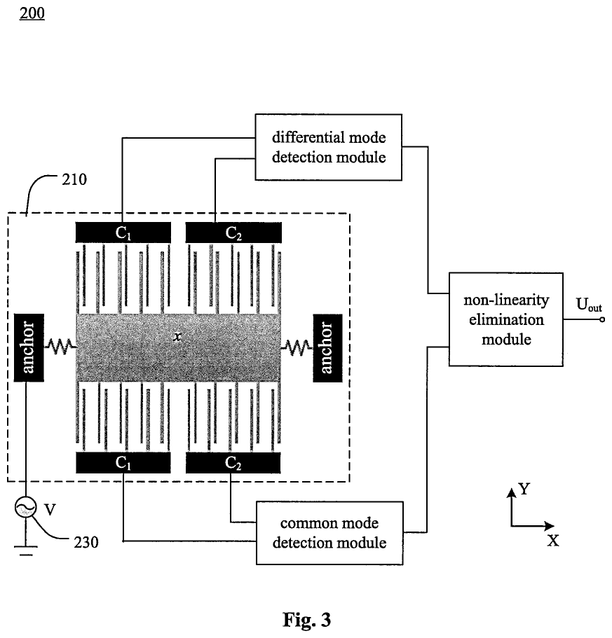

FIG. 3 shows a schematic diagram of a MEMS device according to a first embodiment of the present disclosure. In this embodiment, the MEMS device is, for example, a MEMS accelerometer. As shown in FIG. 3, a MEMS device 200 includes a sensing element 210, an excitation signal 230, a common mode detection module, a differential mode detection module, and a non-linearity elimination module.

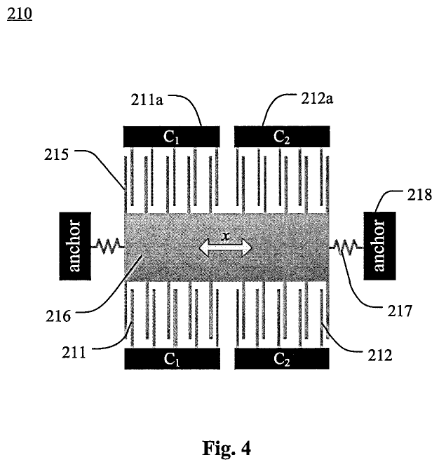

FIG. 4 shows a structural schematic diagram of the MEMS sensing element according to the first embodiment of the present disclosure. As shown in FIG. 4, in this embodiment, the sensing element 210 is an accelerometer, including a movable electrode plate 215, a movable mass 216, a first electrode plate 211, a first fixed electrode 211a, a second electrode plate 212, a second fixed electrode 212a, an elastic beam 217, and an anchor 218.

In this embodiment, there are a plurality of movable electrode plates 215, which are fixedly connected to the movable mass 216. Further, the movable mass 216 is rectangular, and each movable electrode plate 215 is perpendicular to the movable mass 216. Further, the movable mass 216 is connected to the anchor 218 by the elastic beam 217, and when an acceleration is sensed by the MEMS sensing element 210, the movable mass 216 displaces away from a nominal position, the elastic beam 217 deflects in a first direction (e.g., X-axis direction), and the movable mass 216 displaces together with the plurality of movable electrode plates 215 in the first direction (e.g., the X-axis direction).

The first electrode plate 211 and the second electrode plate 212 are fixed electrode plates. In this embodiment, there are a plurality of first electrode plates 211, each first electrode plate 211 overlaps a corresponding movable electrode plate 215, and the plurality of first electrode plates 211 together with the corresponding movable electrode plates 215 form a first capacitor C₁. There are a plurality of second electrode plates 212, each second electrode plate 212 overlaps a corresponding movable electrode plate 215, the plurality of second electrode plates 212 together with the corresponding movable electrode plates 215 form a second capacitor C₂. The first capacitor C₁ and the second capacitor C₂ together form a detection capacitor of the sensing element.

The first electrode plates 211 are located at one side of the movable electrode plates 215, and the second electrode plates 212 are located at the other side of the movable electrode plates 215. When the movable mass 216 and the movable electrode plate 215 move towards the first electrode plate 211, the movable electrode plate 215 moves away from the second electrode plate 212; conversely, when the movable mass 216 and the movable electrode plate 215 move away from the first electrode plate 211, the movable electrode plate 215 moves towards the second electrode plate 212. When the movable mass 216 moves, the capacitance values of the first capacitor C₁ and the second capacitor C₂ change.

When there is no acceleration input, the movable mass 216 is in the nominal position, and the distance between each first electrode plate 211 and the corresponding movable electrode plate 215 is equal to the distance between each second electrode plate 212 and the corresponding movable electrode plate 215. An overlapped area of each first electrode plate 211 with the corresponding movable electrode plate 215 is equal to an overlapped area of each second electrode plate 212 with the corresponding movable electrode plate 215. The number of first electrode plates 211 is equal to the number of second electrode plates 212, and when the movable mass 216 is in its nominal position, the capacitance values of the first capacitor C₁ and the second capacitor C₂ are equal, for example, equal to C₀.

The plurality of first electrode plates 211 are fixedly connected to one or more first fixing electrodes 211a, wherein when there are more than one first fixing electrodes 211a, the first fixing electrodes 211a are short-circuited with each other. The plurality of second electrode plates 212 are fixedly connected to one or more second fixed electrodes 212a, wherein when there are more than one second fixed electrodes 212a, the second fixed electrodes 212a are short-circuited with each other.

The movable electrode plate 215 is connected via the anchor 218 to the excitation signal 230 that provides a high-frequency voltage signal; in a specific embodiment, the excitation signal 230 provides, for example, a high-frequency sinusoidal signal V (e.g., V=V₀ sin ωt, where V₀ represents amplitude, ω represents frequency), and in some other embodiments, V may also be a square wave signal or other waveform. The first electrode plate 211 is connected to the differential mode detection module via the first fixed electrode 211a, and the second electrode plate 212 is connected to the differential mode detection module via the second fixed electrode 212a, that is, the first capacitor C₁ and the second capacitor C₂ are respectively connected to the differential mode detection module. Similarly, the first capacitor C₁ and the second capacitor C₂ are respectively connected to the common mode detection module.

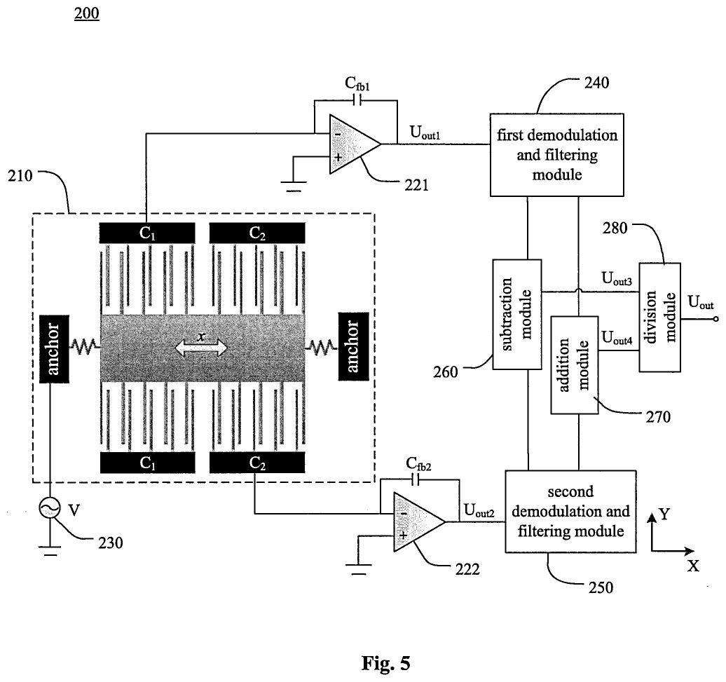

FIG. 5 shows a schematic diagram of an equivalent circuit of the MEMS device according to the first embodiment of the present disclosure; as shown in FIG. 5, the MEMS device further includes a first operational amplifier 221, a first feedback capacitor C_{fb1}, a second operational amplifier 222, a second feedback capacitor C_{fb2}, a first demodulation and filtering module 240, a second demodulation and filtering module 250, a subtraction module 260, an addition module 270, and a division module 280. The first operational amplifier 221, the first feedback capacitor C_{fb1}, the first demodulation and filtering module 240, the second operational amplifier 222, the second feedback capacitor C_{fb2}, the second demodulation and filtering module 250, and the addition module 270 form the common mode detection module; the first operational amplifier 221, the first feedback capacitor C_{fb1}, the first demodulation and filtering module 240, the second operational amplifier 222, the second feedback capacitor C_{fb2}, the second demodulation and filtering module 250, and the subtraction module 260 form the differential mode detection module; The division module 280 forms the non-linearity elimination module.

Specifically, the first electrode plate 211 is connected to an inverting input terminal of the first operational amplifier 221 via the first fixed electrode 211a, and the first feedback capacitor C_{fb1} is connected between the inverting input terminal of the first operational amplifier 221 and an output terminal of the first operational amplifier 221. The second electrode plate 212 is connected to an inverting input terminal of the second operational amplifier 222 via the second fixed electrode 212a, and the second feedback capacitor C_{fb2} is connected between the inverting input terminal of the second operational amplifier 222 and an output terminal of the second operational amplifier 222. Further, capacitance values of the first feedback capacitor C_{fb1} and the second feedback capacitor C_{fb2} are both equal to C_{fb}.

Through the first demodulation and filtering module 240, the output terminal of the first operational amplifier 221 is connected to a corresponding input terminal of the subtraction module 260 and a corresponding input terminal of the addition module 270, respectively; and through the second demodulation and filtering module 250, the output terminal of the second operational amplifier 222 is connected to a corresponding input terminal of the subtraction module 260 and a corresponding input terminal of the addition module 270, respectively. The first demodulation and filtering module 240 is used to demodulate the high-frequency signal output by the first operational amplifier 221 and filter away the demodulated high-frequency signal, and the second demodulation and filtering module 250 is used to demodulate the high-frequency signal output by the second operational amplifier 222 and filter away the demodulated high-frequency signal; the subtraction module 260 is configured to obtain the difference between the signals output by the output terminal of the first operational amplifier 221 and the output terminal of the second operational amplifier 222; the addition module 270 is configured to obtain the sum of the signals output by the output terminal of the first operational amplifier 221 and the output terminal of the second operational amplifier 222.

An output terminal of the subtraction module 260 and an output terminal of the addition module 270 are connected to corresponding input terminals of the division module 280, respectively. The division module 280 is configured to obtain the quotient between the signals output by the output terminal of the subtraction module 260 and the output terminal of the addition module 270, for eliminating the non-linear relationship between an output signal of the division module 280 and a displacement of the movable electrode plate.

Specifically, the output signal Uₒᵤₜ₁ at the output terminal of the first operational amplifier 221 is:

$${U}_{out 1} = - \frac{{C}_{1}}{{C}_{fb}} {V}_{0} sin ω t$$

The output signal Uₒᵤₜ₂ at the output terminal of the second operational amplifier 222 is:

$${U}_{out 2} = - \frac{{C}_{2}}{{C}_{fb}} {V}_{0} sin ω t$$

The first demodulation and filtering module 240 is configured to demodulate the output signal Uₒᵤₜ₁ of the first operational amplifier 221 to generate an output signal Uₒᵤₜ₁′, which is:

$${U}_{out 1}^{′} = - \frac{{C}_{1}}{{C}_{fb}} {V}_{0} sin ω t \cdot sin ω t = - \frac{{C}_{1}}{{C}_{fb}} {V}_{0} \frac{1 - cos 2 ω t}{2}$$

The first demodulation and filtering module 240 continues to perform filtering to generate an output signal Uₒᵤₜ₁″, which is:

$${U}_{out 1}^{″} = - \frac{{C}_{1}}{{C}_{fb}} \frac{{V}_{0}}{2}$$

The second demodulation and filtering module 250 is configured to demodulate the output signal Uₒᵤₜ₂ of the second operational amplifier 222 to generate an output signal Uₒᵤₜ₂′, which is:

$${U}_{out 2}^{′} = - \frac{{C}_{2}}{{C}_{fb}} {V}_{0} sin ω t \cdot sin ω t = - \frac{{C}_{2}}{{C}_{fb}} {V}_{0} \frac{1 - cos 2 ω t}{2}$$

The second demodulation and filtering module 250 continues to perform filtering to generate an output signal Uₒᵤₜ₂″, which is:

$${U}_{out 2}^{″} = - \frac{{C}_{2}}{{C}_{fb}} \frac{{V}_{0}}{2}$$

The output signal Uₒᵤₜ₃ at the output terminal of the subtraction module 260 is:

$${U}_{o u t 3} = {U}_{out 1}^{″} - {U}_{out 2}^{″} = - \frac{{C}_{1} - {C}_{2}}{{C}_{fb}} \frac{{V}_{0}}{2}$$

The output signal Uₒᵤₜ₄ at the output terminal of the addition module 270 is:

$${U}_{o u t 4} = {U}_{out 1}^{″} + {U}_{out 2}^{″} = - \frac{{C}_{1} + {C}_{2}}{{C}_{fb}} \frac{{V}_{0}}{2}$$

The output signal Uₒᵤₜ at the output terminal of the division module 280 is:

$${U}_{o u t} = \frac{{U}_{o u t 3}}{{U}_{o u t 4}} = \frac{{C}_{1} - {C}_{2}}{{C}_{1} + {C}_{2}}$$

When the movable electrode plate 215 is in the nominal position, the capacitance values of the first capacitor C₁ and the second capacitor C₂ are:

$${C}_{1} = \frac{ε {A}_{0}}{{d}_{0}}$$

$${C}_{2} = \frac{ε {A}_{0}}{{d}_{0}}$$

Where d₀ represents the distance between the first electrode plate 211 and the movable electrode plate 215, and also represents the distance between the second electrode plate 212 and the movable electrode plate 215; A₀ represents the total sum of the overlapped areas of the plurality of first electrode plates 211 with the corresponding movable electrode plates 215, and also represents the total sum of the overlapped areas of the plurality of second electrode plates 212 with the corresponding movable electrode plates 215. From the above formula, it can be known that the capacitance values of the first capacitor C₁ and the second capacitor C₂ are equal, and the output signal Uₒᵤₜ of the division module is 0.

When the movable electrode plate 215 displaces in a first direction (e.g., X-axis direction), the distance between the movable electrode plate 215 and the first electrode plate 211 and the distance between the movable electrode plate 215 and the second electrode plate 212 change, thereby changing the capacitance values of the first capacitor C₁ and the second capacitor C₂.

When the movable electrode plate 215 displaces a distance x, for example, along a direction towards the first electrode plate 211, the distance between the movable electrode plate 215 and the first electrode plate 211 is d₀−x; at the same time, the distance between the movable electrode plate 215 and the second electrode plate 212 is d₀+x, thus the capacitance values of the first capacitor C₁ and the second capacitor C₂ may change,

$${C}_{1} = \frac{ε {A}_{0}}{{d}_{0} - x}$$

$${C}_{2} = \frac{ε {A}_{0}}{{d}_{0} + x}$$

The output signal Uₒᵤₜ₁ at the output terminal of the first operational amplifier 221 is as follows:

$${U}_{o u t 1} = - \frac{\frac{ε {A}_{o}}{{d}_{0} - x}}{{C}_{fb}} {V}_{0} sin ω t = - {V}_{0} sin ω t \frac{ε {A}_{0}}{{C}_{fb}} \frac{1}{{d}_{0} - x}$$

The output signal Uₒᵤₜ₂ at the output terminal of the second operational amplifier 222 is as follows:

$${U}_{o u t 2} = - \frac{\frac{ε {A}_{0}}{{d}_{0} + x}}{{C}_{fb}} {V}_{0} sin ω t = - {V}_{0} sin ω t \frac{ε {A}_{0}}{{C}_{fb}} \frac{1}{{d}_{0} + x}$$

The first demodulation and filtering module 240 is configured to demodulate the output signal Uₒᵤₜ of the first operational amplifier 221 to generate an output signal Uₒᵤₜ₁′, which is:

$${U}_{out 1}^{′} = - \frac{ε {A}_{0}}{{C}_{fb}} \frac{1}{{d}_{0} - x} {V}_{0} sin ω t \cdot sin ω t = - \frac{ε {A}_{0}}{{C}_{fb}} \frac{1}{{d}_{0} - x} {V}_{0} \frac{1 - cos 2 ω t}{2}$$

The first demodulation and filtering module 240 continues to perform filtering to generate an output signal Uₒᵤₜ₁″, which is:

$${U}_{out 1}^{″} = - \frac{ε {A}_{0}}{{C}_{fb}} \frac{1}{{d}_{0} - x} \frac{{V}_{0}}{2}$$

The second demodulation and filtering module 250 is configured to demodulate the output signal Uₒᵤₜ₂ of the second operational amplifier 222 to generate an output signal Uₒᵤₜ₂′, which is:

$${U}_{out 2}^{′} = - \frac{ε {A}_{0}}{{C}_{fb}} \frac{1}{{d}_{0} + x} {V}_{0} sin ω t \cdot sin ω t = - \frac{ε {A}_{0}}{{C}_{fb}} \frac{1}{{d}_{0} + x} {V}_{0} \frac{1 - cos 2 ω t}{2}$$

The second demodulation and filtering module 250 continues to perform filtering to generate an output signal Uₒᵤₜ₂″, which is:

$${U}_{out 2}^{″} = - \frac{ε {A}_{0}}{{C}_{fb}} \frac{1}{{d}_{0} + x} \frac{{V}_{0}}{2}$$

The output signal Uₒᵤₜ₃ at the output terminal of the subtraction module 260 is as follows:

$${U}_{o u t 3} = {U}_{out 1}^{″} - {U}_{out 2}^{″} = - \frac{{V}_{0}}{2} \frac{ε {A}_{0}}{{C}_{fb}} ( \frac{1}{{d}_{0} - x} - \frac{1}{{d}_{0} + x} )$$

The output signal Uₒᵤₜ₄ at the output terminal of the addition module 270 is as follows:

$${U}_{o u t 4} = {U}_{out 1}^{″} + {U}_{out 2}^{″} = - \frac{{V}_{0}}{2} \frac{ε {A}_{0}}{{C}_{fb}} ( \frac{1}{{d}_{0} - x} + \frac{1}{{d}_{0} + x} )$$

The output signal Uₒᵤₜ at the output terminal of the division module 280 is as follows:

$${U}_{out} = \frac{{U}_{out 3}}{{U}_{out 4}} = \frac{x}{{d}_{0}}$$

From the above formula, it can be known that the output signal Uₒᵤₜ of the division module 280 is proportional to the displacement of the movable electrode plate 215, that is, the output signal Uₒᵤₜ of the division module 280 is linear with the displacement of the movable electrode plate 215.

It should be noted that a first analog-to-digital conversion module (ADC) and the second analog-to-digital conversion module (ADC) can be further arranged, and the first analog-to-digital conversion module can be connected between the output terminal of the first operational amplifier 221 and the input terminal of the first demodulation and filtering module 240, that is, the analog output signal of the first operational amplifier 221 is converted to a digital output signal, which is then demodulated and filtered in digital domain; alternatively, the first analog-to-digital conversion module can also be connected from the output terminal of the first demodulation and filtering module 240 to a corresponding input terminal of the addition module 270 and a corresponding input terminal of the subtraction module 260, that is, demodulating and filtering are performed in analog domain, and then the demodulated and filtered output signal is converted into digital output signal, which is then input into the addition module 270 and the subtraction module 260; alternatively, the first analog-to-digital conversion module can also be connected between the output terminal of the subtraction module 260 and a corresponding input terminal of the division module 280. Similarly, the second analog-to-digital conversion module can be connected between the output terminal of the second operational amplifier 222 and the input terminal of the second demodulation and filtering module 250; alternatively, the second analog-to-digital conversion module may also be connected from the output terminal of the second demodulation and filtering module 250 to a corresponding input terminal of the addition module 270 and a corresponding input terminal of the subtraction module 260; alternatively, the second analog-to-digital conversion module can also be connected between the output terminal of the addition module 270 and a corresponding input terminal of the division module 280. This embodiment is not limited hereto.

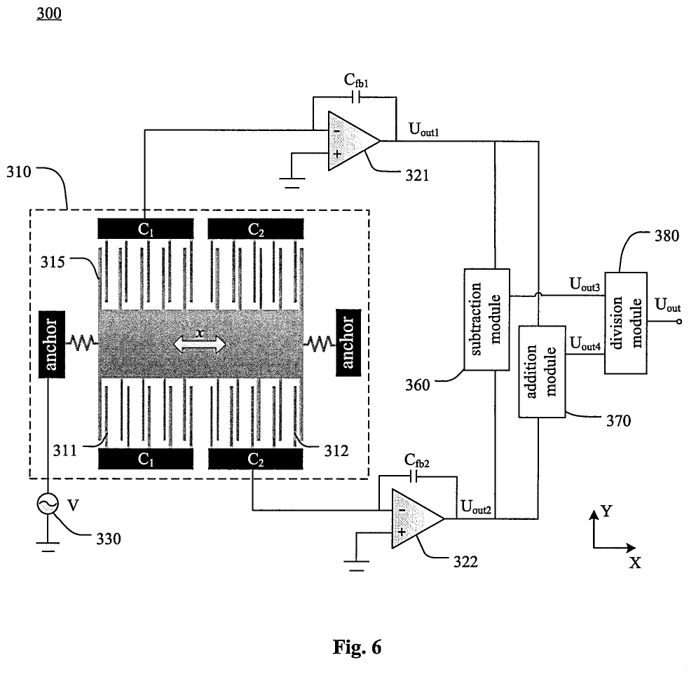

FIG. 6 shows a schematic diagram of a MEMS device according to a second embodiment of the present disclosure; in this embodiment, the MEMS device is, for example, a MEMS accelerometer. As shown in FIG. 6, the MEMS device 300 includes a sensing element 310, an excitation signal 330, a common mode detection module, a differential mode detection module, and a non-linearity elimination module. In this embodiment, the sensing element 310 is an accelerometer.

Different from the first embodiment, in this embodiment, the first demodulation and filtering module and the second demodulation and filtering module are omitted, and the output terminal of the first operational amplifier 321 and the output terminal of the second operational amplifier 322 are respectively connected to the input terminals of the subtraction module 360; at the same time, the output terminal of the first operational amplifier 321 and the output terminal of the second operational amplifier 322 are connected to the input terminals of the addition module 370, respectively. The subtraction module 360 is configured to obtain the difference between the output signal of the first operational amplifier 321 and the output signal of the second operational amplifier 322; the addition module 370 is configured to obtain the sum of the output signal of the first operational amplifier 321 and the output signal of the second operational amplifier 322.

The output terminal of the subtraction module 360 and the output terminal of the addition module 370 are connected to the input terminals of the division module 380, respectively. The division module 380 is configured to obtain the quotient between the output signal of the subtraction module 360 and the output signal of the addition module 370, thus eliminating the non-linear relationship between the output signal of the division module 380 and the displacement of the movable electrode plate.

Specifically, the output signal Uₒᵤₜ₁ at the output terminal of the first operational amplifier 321 is:

$${U}_{out 1} = - \frac{{C}_{1}}{{C}_{fb}} {V}_{0} sin ω t$$

The output signal Uₒᵤₜ₂ at the output terminal of the second operational amplifier 322 is:

$${U}_{out 2} = - \frac{{C}_{2}}{{C}_{fb}} {V}_{0} sin ω t$$

The output signal Uₒᵤₜ₃ at the output terminal of the subtraction module 360 is:

$${U}_{out 3} = {U}_{out 1} - {U}_{out 2} = - \frac{{C}_{1} - {C}_{2}}{{C}_{fb}} {V}_{0} sin ω t$$

The output signal Uₒᵤₜ₄ at the output terminal of the addition module 370 is:

$${U}_{out 4} = {U}_{out 1} + {U}_{out 2} = - \frac{{C}_{1} + {C}_{2}}{{C}_{fb}} {V}_{0} sin ω t$$

The output signal Uₒᵤₜ at the output terminal of the division module 380 is:

$${U}_{out} = \frac{{U}_{out 3}}{{U}_{out 4}} = \frac{{C}_{1} - {C}_{2}}{{C}_{1} + {C}_{2}}$$

When the movable electrode plate 315 is in the nominal position, the capacitance values of the first capacitor C₁ and the second capacitor C₂ are:

$$\begin{matrix}{C}_{1} = \frac{ε {A}_{0}}{{d}_{0}} \\ {C}_{2} = \frac{ε {A}_{0}}{{d}_{0}}\end{matrix}$$

Where d₀ represents the distance between the first electrode plate 311 and the movable electrode plate 315, and the distance between the second electrode plate 312 and the movable electrode plate 315; A₀ is the total sum of the overlapped areas of the plurality of first electrode plates 311 with the corresponding movable electrode plates 315, while A₀ is also the total sum of the overlapped areas of the plurality of second electrode plates 312 with the corresponding movable electrode plates 315. From the above formula, it can be known that the capacitance values of the first capacitor C₁ and the second capacitor C₂ are equal, and the output signal Uₒᵤₜ of the division module is 0.

When the movable electrode plate 315 displaces in a first direction (e.g., in X-axis direction), the distance between the movable electrode plate 315 and the first electrode plate 311 and the distance between the movable electrode plate 315 and the second electrode plate 312 change, thereby causing the capacitance values of the first capacitor C₁ and the second capacitor C₂ to change.

When the movable electrode plate 315 displaces a distance x, for example, along a direction towards the first electrode plate 311, the distance between the movable electrode plate 315 and the first electrode plate 311 is d₀−x; at the same time, the distance between the movable electrode plate 315 and the second electrode plate 312 is d₀+x; thus, the capacitance values of the first capacitor C₁ and the second capacitor C₂ may change, specifically:

$$\begin{matrix}{C}_{1} = \frac{ε {A}_{0}}{{d}_{0} - x} \\ {C}_{2} = \frac{ε {A}_{0}}{{d}_{0} + x}\end{matrix}$$

The output signal Uₒᵤₜ₁ at the output terminal of the first operational amplifier 321 is as follows:

$${U}_{out 1} = - \frac{\frac{ε {A}_{0}}{{d}_{0} - x}}{{C}_{fb}} {V}_{0} sin ω t = - {V}_{0} sin ω t \frac{ε {A}_{0}}{{C}_{fb}} \frac{1}{{d}_{0} - x}$$

The output signal Uₒᵤₜ₂ at the output terminal of the second operational amplifier 322 is as follows:

$${U}_{out 2} = - \frac{\frac{ε {A}_{0}}{{d}_{0} + x}}{{C}_{fb}} {V}_{0} sin ω t = - {V}_{0} sin ω t \frac{ε {A}_{0}}{{C}_{fb}} \frac{1}{{d}_{0} + x}$$

The output signal Uₒᵤₜ₃ at the output terminal of the subtraction module 360 is as follows:

$${U}_{out 3} = {U}_{out 1} - {U}_{out 2} = - {V}_{0} sin ω t \frac{ε {A}_{0}}{{C}_{fb}} ( \frac{1}{{d}_{0} - x} - \frac{1}{{d}_{0} + x} )$$

The output signal Uₒᵤₜ₄ at the output terminal of the addition module 370 is as follows:

$${U}_{out 4} = {U}_{out 1} + {U}_{out 2} = - {V}_{0} sin ω t \frac{ε {A}_{0}}{{C}_{fb}} ( \frac{1}{{d}_{0} - x} + \frac{1}{{d}_{0} + x} )$$

The output signal Uₒᵤₜ at the output terminal of the division module 380 is as follows:

$${U}_{out} = \frac{{U}_{out 3}}{{U}_{out 4}} = \frac{x}{{d}_{0}}$$

From the above formula, it can be known that the output signal Uₒᵤₜ of the division module 380 is proportional to the displacement of the movable electrode plate 315, that is, the output signal Uₒᵤₜ of the division module 380 is linear with the displacement of the movable electrode plate 315. At the same time, in this embodiment, the division module directly realizes the demodulation of high-frequency excitation signals which are respectively output by the first operational amplifier 321 and the second operational amplifier 322 at the same time, with the first demodulation and filtering module and the second demodulation and filtering module being omitted, thus simplifying the device.

It should be noted that the output terminal of the first operational amplifier 321 can be directly connected to a corresponding input terminal of the addition module 370 and a corresponding input terminal of the subtraction module 360, or can be respectively connected to the corresponding input terminal of the addition module 370 and the corresponding input terminal of the subtraction module 360 via an analog-to-digital conversion module (ADC); similarly, the output terminal of the second operational amplifier 322 can be directly connected to a corresponding input terminal of the addition module 370 and a corresponding input terminal of the subtraction module 360, or can be respectively connected to the corresponding input terminal of the addition module 370 and the corresponding input terminal of the subtraction module 360 via an analog-to-digital conversion module (ADC). This embodiment is not limited hereto. As an example, a first analog-to-digital conversion module and a second analog-to-digital conversion module can be provided. The first analog-to-digital conversion module can be connected from the output terminal of the first operational amplifier 321 to a corresponding input terminal of the addition module 370 and a corresponding input terminal of the subtraction module 360, that is, an analog output signal of the first operational amplifier 321 is converted to a digital output signal, which is then input to the addition module 370 and the subtraction module 360; alternatively, the first analog-to-digital conversion module can also be connected between the output terminal of the subtraction module 360 and a corresponding input terminal of the division module 380, that is, the difference between the output signal of the first operational amplifier 321 and the output signal of the second operational amplifier 322 can be obtained in analog domain, and then converted into a digital output signal which is input to the division module 380. Similarly, the second analog-to-digital conversion module can be connected from the output terminal of the second operational amplifier 322 to a corresponding input terminal of the addition module 370 and a corresponding input terminal of the subtraction module 360, that is, an analog output signal of the second operational amplifier 322 is converted into a digital output signal, which is then input to the addition module 370 and the subtraction module 360; alternatively, the second analog-to-digital conversion module can also be connected between the output terminal of the addition module 370 and a corresponding input terminal of the division module 380, that is, the sum of the output signals of the first operational amplifier 321 and the second operational amplifier 322 can be obtained in analog domain, and is then converted into a digital output signal, which is input to the division module 380. This embodiment is not limited hereto.

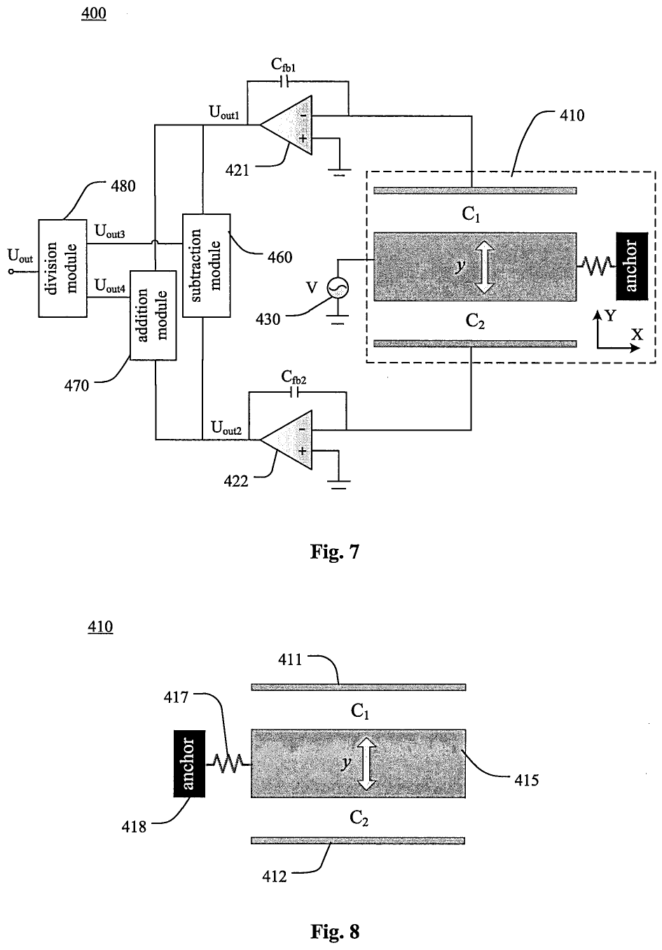

FIG. 7 shows a schematic diagram of a MEMS device according to a third embodiment of the present disclosure. In this embodiment, the MEMS device is, for example, a MEMS accelerometer. As shown in FIG. 7, in this embodiment, the MEMS device 400 includes a sensing element 410, an excitation signal 430, a common mode detection module, a differential mode detection module, and a non-linearity elimination module.

Unlike the second embodiment, in this embodiment, the sensing element has a “sandwich-type” structure.

FIG. 8 shows a structural schematic diagram of the MEMS sensing element 410 according to the third embodiment of the present disclosure. As shown in FIG. 8, in this embodiment, the sensing element 410 includes a movable electrode plate 415, a first electrode plate 411, a second electrode plate 412, an elastic beam 417, and an anchor 418. The first electrode plate 411 is located at one side of the movable electrode plate 415, the second electrode plate 412 is located at the other side of the movable electrode plate 415, a first capacitor C₁ is formed between the first electrode plate 411 and the movable electrode plate 415, and a second capacitor C₂ is formed between the second electrode plate 412 and the movable electrode plate 415.

The movable electrode plate 415 is connected to the anchor 418 via the elastic beam 417, and when an acceleration along Y-axis direction is applied to the MEMS device, the movable electrode plate 415 moves away from the nominal position along the Y-axis direction, so that capacitance values of the first capacitor C₁ and the second capacitor C₂ may change. The first electrode plate 411 is connected to an inverting input terminal of the first operational amplifier 421, and the second electrode plate 412 is connected to an inverting input terminal of the second operational amplifier 422.

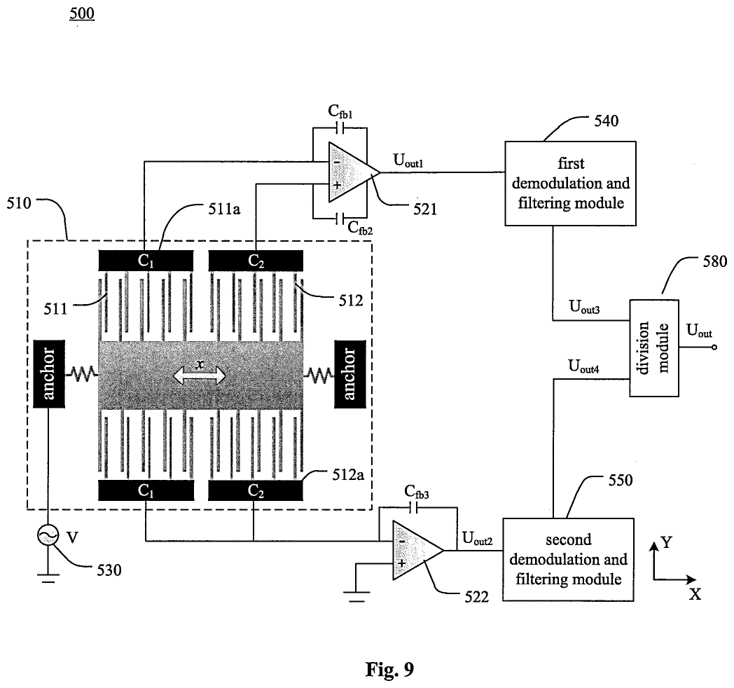

FIG. 9 shows a schematic diagram of a MEMS device according to a fourth embodiment of the present disclosure. In this embodiment, the MEMS device is, for example, a MEMS accelerometer. As shown in FIG. 9, unlike the first embodiment, in this embodiment, a differential mode detection module includes a first operational amplifier 521, a first feedback capacitor C_{fb1}, and a second feedback capacitor C_{fb2}; a common mode detection module includes a second operational amplifier 522, a third feedback capacitor C_{fb3}.

A first electrode plate 511 is connected to an inverting input terminal of the first operational amplifier 521 via a first fixed electrode 511a, a second electrode plate 512 is connected to a non-inverting input terminal of the first operational amplifier 521 via a second fixed electrode 512a, the first feedback capacitor C_{fb1} is connected between the inverting input terminal of the first operational amplifier 521 and an output terminal of the first operational amplifier 521, and the second feedback capacitor C_{fb2} is connected between the non-inverting input terminal of the first operational amplifier 521 and the output terminal of the first operational amplifier 521. The first electrode plate 511 is connected to an inverting input terminal of the second operational amplifier 522 via the first fixed electrode 511a, the second electrode plate 512 is connected to the inverting input terminal of the second operational amplifier 522 via the second fixed electrode 512a, and the third feedback capacitor Cos is connected between the inverting input terminal of the second operational amplifier 522 and an output terminal of the second operational amplifier 522. Further, the capacitance values of the first feedback capacitor C_{fb1} and the second feedback capacitor C_{fb2} are both equal to C_{fb}; the capacitance value C_{fb}′ of the third feedback capacitor C_{fb3}, which can be equal to C_{fb} or different from C_{fb}.

The output terminal of the first operational amplifier 521 is connected to a corresponding input terminal of the division module 580 via the first demodulation and filtering module 540, and the output terminal of the second operational amplifier 522 is connected to a corresponding input terminal of the division module 580 via the second demodulation and filtering module 550. The first demodulation and filtering module 540 is used to demodulate the high frequency excitation signal output by the first operational amplifier 521 and perform filtering on the demodulated high frequency excitation signal, and the second demodulation and filtering module 550 is used to demodulate the high frequency excitation signal output by the second operational amplifier 522 and perform filtering on the demodulated high frequency excitation signal. The division module 580 is configured to obtain the quotient between the output signal of the first operational amplifier 521 and the output signal of the second operational amplifier 522, thus eliminating the non-linear relationship between the output signal of the division module 580 and the displacement of the movable electrode plate.

Specifically, the output signal Uₒᵤₜ₁ at the output terminal of the first operational amplifier 521 is:

$${U}_{out 1} = - \frac{{C}_{1} - {C}_{2}}{{C}_{fb}} {V}_{0} sin ω t$$

The output signal Uₒᵤₜ₂ at the output terminal of the second operational amplifier 522 is:

$${U}_{out 2} = - \frac{{C}_{1} + {C}_{2}}{{C}_{fb}^{′}} {V}_{0} sin ω t$$

The first demodulation and filtering module 540 is configured to demodulate the output signal Uₒᵤₜ₁ of the first operational amplifier 521 to generate an output signal Uₒᵤₜ₁′, which is:

$${U}_{out 1}^{′} = - \frac{{C}_{1} - {C}_{2}}{{C}_{fb}} {V}_{0} sin ω t \cdot sin ω t = - \frac{{C}_{1} - {C}_{2}}{{C}_{fb}} {V}_{0} \frac{1 - cos 2 ω t}{2}$$

The first demodulation and filtering module 540 continues to perform filtering to generate the output signal Uₒᵤₜ₃, which is:

$${U}_{out 3} = - \frac{{C}_{1} - {C}_{2}}{{C}_{fb}} \frac{{V}_{0}}{2}$$

The second demodulation and filtering module 550 is configured to demodulate the output signal Uₒᵤₜ₂ of the second operational amplifier 522 to generate an output signal Uₒᵤₜ₂′, which is:

$${U}_{out 2}^{′} = - \frac{{C}_{1} + {C}_{2}}{{C}_{fb}^{′}} {V}_{0} sin ω t \cdot sin ω t = - \frac{{C}_{1} + {C}_{2}}{{C}_{fb}^{′}} {V}_{0} \frac{1 - cos 2 ω t}{2}$$

The second demodulation and filtering module 550 continues to perform filtering to generate an output signal Uₒᵤₜ₄, which is:

$${U}_{out 4} = - \frac{{C}_{1} + {C}_{2}}{{C}_{fb}^{′}} \frac{{V}_{0}}{2}$$

An output signal Uₒᵤₜ at the output terminal of the division module 580 is:

$${U}_{out} = \frac{{U}_{out 3}}{{U}_{out 4}} = \frac{{C}_{fb}^{′}}{{C}_{fb}} \frac{{C}_{1} - {C}_{2}}{{C}_{1} + {C}_{2}}$$

When the movable electrode plate 515 is in the nominal position, the capacitance values of the first capacitor C₁ and the second capacitor C₂ are:

$${C}_{1} = \frac{ε {A}_{0}}{{d}_{0}} \\ {C}_{2} = \frac{ε {A}_{0}}{{d}_{0}}$$

Where d₀ represents the distance between the first electrode plate 511 and the movable electrode plate 515, and also represents the distance between the second electrode plate 512 and the movable electrode plate 515; A₀ represents the total sum of the overlapped areas of the plurality of first electrode plates 511 with the corresponding movable electrode plates 515, and also represents the total sum of the overlapped areas of the plurality of second electrode plates 512 with the corresponding movable electrode plates 515. From the above formula, it can be known that the capacitance values of the first capacitor C₁ and the second capacitor C₂ are equal, and the output signal Uₒᵤₜ of the division module is 0.

When the movable electrode plate 515 displaces in a first direction (e.g., in X-axis direction), the distance between the movable electrode plate 515 and the first electrode plate 511 and the distance between the movable electrode plate 515 and the second electrode plate 512 change, thereby causing the capacitance values of the first capacitor C₁ and the second capacitor C₂ to change.

When the movable electrode plate 515 displaces a distance x, for example, along a direction towards the first electrode plate 511, the distance between the movable electrode plate 515 and the first electrode plate 511 is d₀−x; at the same time, the distance between the movable electrode plate 515 and the second electrode plate 512 is d₀+x; then, the capacitance values of the first capacitor C₁ and the second capacitor C₂ may change, specifically:

$${C}_{1} = \frac{ε {A}_{0}}{{d}_{0} - x} \\ {C}_{2} = \frac{ε {A}_{0}}{{d}_{0} + x}$$

The output signal Uₒᵤₜ₁ at the output terminal of the first operational amplifier 521 is as follows:

$${U}_{out 1} = - \frac{\frac{ε {A}_{0}}{{d}_{0} - x} - \frac{ε {A}_{0}}{{d}_{0} + x}}{{C}_{fb}} {V}_{0} sin ω t = - {V}_{0} sin ω t \frac{ε {A}_{0}}{{C}_{fb}} ( \frac{1}{{d}_{0} - x} - \frac{1}{{d}_{0} + x} )$$

The output signal Uₒᵤₜ₂ at the output terminal of the second operational amplifier 522 is as follows:

$${U}_{out 2} = - \frac{\frac{ε {A}_{01}}{{d}_{0} + x} + \frac{ε {A}_{0}}{{d}_{0} + x}}{{C}_{fb}^{′}} {V}_{0} sin ω t = - {V}_{0} sin ω t \frac{ε {A}_{0}}{{C}_{fb}^{′}} ( \frac{1}{{d}_{0} - x} + \frac{1}{{d}_{0} + x} )$$

The first demodulation and filtering module 540 is configured to demodulate of the output signal Uₒᵤₜ₁ of the first operational amplifier 521 to generate the output signal Uₒᵤₜ₁′, which is:

$${U}_{out 1}^{′} = - \frac{ε {A}_{0}}{{C}_{fb}} ( \frac{1}{{d}_{0} - x} - \frac{1}{{d}_{0} + x} ) {V}_{0} sin ω t \cdot sin ω t = - \frac{ε {A}_{0}}{{C}_{fb}} ( \frac{1}{{d}_{0} - x} - \frac{1}{{d}_{0} + x} ) {V}_{0} \frac{1 - cos 2 ω t}{2}$$

The first demodulation and filtering module 540 continues to perform filtering to generate the output signal Uₒᵤₜ₃, which is:

$${U}_{out 3} = - \frac{ε {A}_{0}}{{C}_{fb}} ( \frac{1}{{d}_{0} - x} - \frac{1}{{d}_{0} + x} ) \frac{{V}_{0}}{2}$$

The second demodulation and filtering module 550 is configured to demodulate the output signal Uₒᵤₜ₂ of the second operational amplifier 522 to generate the output signal Uₒᵤₜ₂′, which is:

$${U}_{out 2}^{′} = - \frac{ε {A}_{0}}{{C}_{fb}^{′}} ( \frac{1}{{d}_{0} - x} + \frac{1}{{d}_{0} + x} ) {V}_{0} sin ω t \cdot sin ω t = - \frac{ε {A}_{0}}{{C}_{fb}^{′}} ( \frac{1}{{d}_{0} - x} + \frac{1}{{d}_{0} + x} ) {V}_{0} \frac{1 - cos 2 ω t}{2}$$

The second demodulation and filtering module 550 continues to perform filtering to generate the output signal Uₒᵤₜ₄, which is:

$${U}_{out 4} = - \frac{ε {A}_{0}}{{C}_{fb}^{′}} ( \frac{1}{{d}_{0} - x} + \frac{1}{{d}_{0} + x} ) \frac{{V}_{0}}{2}$$

The output signal Uₒᵤₜ at the output terminal of the division module 580 is as follows:

$${U}_{out} = \frac{{U}_{out 3}}{{U}_{out 4}} = \frac{{C}_{fb}^{′}}{{C}_{fb}} \frac{x}{{d}_{0}}$$

From the above formula, it can be known that the output signal of the division module 580 is proportional to the displacement of the movable electrode plate 515, that is, the output signal Uₒᵤₜ of the division module 580 is linear with the displacement of the movable electrode plate 515.

In this embodiment, the first demodulation and filtering module 540 and the second demodulation and filtering module 550 can be omitted. When the first demodulation and filtering module 540 and the second demodulation and filtering module 550 are omitted, the output signal Uₒᵤₜ at the output terminal of the division module 580 is as follows:

$${U}_{out} = \frac{{U}_{out 1}}{{U}_{out 2}} = \frac{{C}_{fb}^{′}}{{C}_{fb}} \frac{x}{{d}_{0}}$$

Similarly, the output terminal of the first operational amplifier 521 may be directly connected to the input terminal of the first demodulation and filtering module 540 or a corresponding input terminal of the division module 580, or may be connected to the input terminal of the first demodulation and filtering module 540 or a corresponding input terminal of the division module 580 via an analog-to-digital conversion module (ADC); similarly, the output terminal of the second operational amplifier 522 can be directly connected to the input terminal of the second demodulation and filtering module 550 or a corresponding input terminal of the division module 580, or can be connected to the input terminal of the second demodulation and filtering module 550 or a corresponding input terminal of the division module 580 via an analog-to-digital conversion module (ADC). The present embodiment is not limited hereto.

In the above embodiments, the MEMS device may include a MEMS accelerometer, which may be equivalent to a parallel plate capacitor including a detection capacitor (including the first capacitor and the second capacitor). In other embodiments, the MEMS device may include any other MEMS sensing element, which may be equivalent to a parallel plate capacitor including a detection capacitor (including the first capacitor and the second capacitor). In a specific embodiment, the MEMS device is, for example, a MEMS gyroscope or the like.

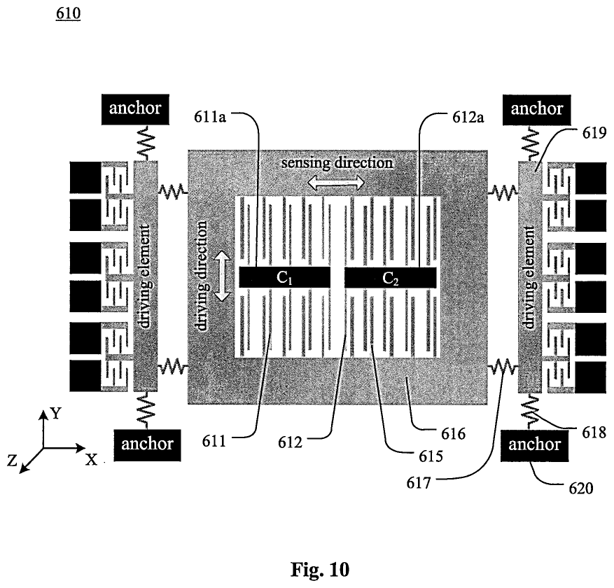

FIG. 10 illustrates a schematic diagram of a MEMS gyroscope sensing element 610 including a movable electrode plate 615, a movable mass 616, a first electrode plate 611, a first fixed electrode 611a, a second electrode plate 612, a second fixed electrode 612a, an elastic beam 617, an elastic beam 618, a driving element 619, an anchor 620.

In this embodiment, the movable electrode plate 615, the first electrode plate 611, and the second electrode plate 612 are arranged in a same way as in the second embodiment, that is, the first capacitor C₁ is formed between the first electrode plate 611 and the movable electrode plate 615, and the second capacitor C₂ is formed between the second electrode plate 612 and the movable electrode plate 615.

The first capacitor C₁ and the second capacitor C₂ are connected to corresponding input terminals of the common mode detection module, while the first capacitor C₁ and the second capacitor C₂ are connected to corresponding input terminals of the differential mode detection module. The output terminal of the differential mode detection module and the output terminal of the common mode detection module are connected to corresponding input terminals of the non-linearity elimination module. Connection configuration among the common mode detection module, the differential mode detection module, and the non-linearity elimination module can be the same as any of the above embodiments, and will not be described in detail here in this embodiment.

In this embodiment, there are a plurality of movable electrode plates 615, which are fixedly connected to the movable mass 616. Further, the movable mass 616 is an annular mass, and the movable electrode plates 615 are fixed to two opposing inner sidewalls of the annular movable mass 616. Further, the movable mass 616 is connected to the driving element 619 through the elastic beam 617, two ends of the driving element 619 are connected to the anchor 620 through the elastic beam 618, and the driving element 619 is configured to drive the movable mass 616 to perform resonant vibration along the Y-axis direction shown in the figure under the actuation of a driving force. When there is angular velocity input along Z-axis direction, a Coriolis force is generated along the X-axis direction, so that the movable mass 616 and the movable electrode plate 615 may vibration along the X-axis direction.

When there is no angular velocity input, the movable electrode plate 615 is positioned in the nominal position along the X-axis direction, and the first capacitor C₁ and the second capacitor C₂ are equal, for example, equal to C₀. When there is an angular velocity input along the Z-axis direction, the movable electrode plate 615 is vibrated for a displacement x along the X-axis direction under the actuation of the Coriolis force. And the capacitance values of the first capacitor C₁ and the second capacitor C₂ may change.

It should be noted that, according to some embodiments of the present disclosure, the modules, such as the differential mode detection module, the non-linearity elimination module, the common mode detection module, can be implemented by one or more corresponding circuit including electronic elements; and according to some embodiments of the present disclosure, the modules, such as the first demodulation and filtering module, the subtraction module, the addition module, the division module and the second demodulation and filtering module, can be implemented by one or more corresponding circuit including electronic elements.

In accordance with the embodiments of the present disclosure, such as described above, these embodiments do not describe all details, nor do they limit the invention to the specific embodiments described. Obviously, a lot of modifications and changes can be made based on the above description. These embodiments are selected and specifically described in this specification in order to better explain the principles and practical applications of the present disclosure, so that those skilled in the art can make good use of the present disclosure and its modifications on the basis of the present disclosure. The present disclosure is limited only by the claims and their full scope and equivalents.

What is claimed is:

1. A MEMS device, comprising:
a sensing element, comprising a movable electrode plate, a first electrode plate located at a first side of the movable electrode plate and a second electrode plate located at a second side of the movable electrode plate, the first electrode plate and the movable electrode plate forming a first capacitor; the second electrode plate and the movable electrode plate forming a second capacitor; the first capacitor and the second capacitor together forming a detection capacitor of the sensing element;
a differential mode detection module, wherein the first capacitor and the second capacitor are respectively connected to corresponding input terminals of the differential mode detection module, and the differential mode detection module is configured to perform differential mode detection on the first capacitor and the second capacitor;
a common mode detection module, wherein the first capacitor and the second capacitor are respectively connected to corresponding input terminals of the common mode detection module, and the common mode detection module is configured to perform common mode detection on the first capacitor and the second capacitor; and
a non-linearity elimination module, wherein an output terminal of the differential mode detection module and an output terminal of the common mode detection module are respectively connected to corresponding input terminals of the non-linearity elimination module, and the non-linearity elimination module is configured to eliminate a nonlinear relationship between a capacitance variation of the detection capacitor of the sensing element and a displacement of the movable electrode plate.

2. The MEMS device according to claim 1, wherein an overlapped area of the first electrode plate with the movable electrode plate is equal to an overlapped area of the second electrode plate with the movable electrode plate.

3. The MEMS device according to claim 1, wherein when the movable electrode plate is in a nominal position, a distance between the first electrode plate and the movable electrode plate and a distance between the second electrode plate and the movable electrode plate are equal.

4. The MEMS device according to claim 1, wherein the MEMS device comprises:
a first operational amplifier, the first electrode plate being connected to an inverting input terminal of the first operational amplifier; and
a first feedback capacitor, connected between the inverting input terminal of the first operational amplifier and an output terminal of the first operational amplifier;
a second operational amplifier, the second electrode plate being connected to an inverting input terminal of the second operational amplifier; and
a second feedback capacitor, connected between the inverting input terminal of the second operational amplifier and an output terminal of the second operational amplifier, wherein a capacitance value of the first feedback capacitor is equal to a capacitance value of the second feedback capacitor;
a subtraction module, the output terminal of the first operational amplifier and the output terminal of the second operational amplifier being connected to input terminals of the subtraction module, respectively;
an addition module, the output terminal of the first operational amplifier and the output terminal of the second operational amplifier being connected to input terminals of the addition module, respectively;
wherein the differential mode detection module is formed by the first operational amplifier, the first feedback capacitor, the second operational amplifier, the second feedback capacitor, and the subtraction module; the common mode detection module is formed by the first operational amplifier, the first feedback capacitor, the second operational amplifier, the second feedback capacitor, and the addition module.

5. The MEMS device according to claim 4, further comprising:
a first demodulation and filtering module, through which the output terminal of the first operational amplifier is connected to a corresponding input terminal of the addition module and a corresponding input terminal of the subtraction module, respectively;
a second demodulation and filtering module, through which the output terminal of the second operational amplifier is connected to a corresponding input terminal of the addition module and a corresponding input terminal of the subtraction module, respectively.

6. The MEMS device according to claim 1, wherein the differential mode detection module comprises:
a first operational amplifier, wherein the first electrode plate is connected to an inverting input terminal of the first operational amplifier, and the second electrode plate is connected to a non-inverting input terminal of the first operational amplifier;
a first feedback capacitor, connected between the inverting input terminal of the first operational amplifier and an output terminal of the first operational amplifier;
a second feedback capacitor, connected between the non-inverting input terminal of the first operational amplifier and the output terminal of the first operational amplifier, wherein a capacitance value of the first feedback capacitor is equal to a capacitance value of the second feedback capacitor;
wherein the common mode detection module comprises:
a second operational amplifier, the first electrode plate and the second electrode plate being connected to an inverting input terminal of the second operational amplifier, respectively;
a third feedback capacitor, connected between the inverting input terminal of the second operational amplifier and an output terminal of the second operational amplifier.

7. The MEMS device according to claim 1, wherein the non-linearity elimination module is a division module.

8. The MEMS device according to claim 6, further comprising:
a first demodulation and filtering module, through which the output terminal of the first operational amplifier is connected to a corresponding input terminal of the non-linearity elimination module;
a second demodulation and filtering module, through which the output terminal of the second operational amplifier is connected to a corresponding input terminal of the non-linearity elimination module.

9. The MEMS device according to claim 1, wherein the MEMS device further comprises an excitation signal, which is connected to the movable electrode plate for providing an excitation voltage to the first capacitor and the second capacitor.

10. The MEMS device according to claim 1, wherein the MEMS device is a MEMS accelerometer.

11. The MEMS device according to claim 1, wherein the MEMS device is a MEMS gyroscope.
